(19) United States
(12) Patent Application Publication
(10) Pub. No.: US 2006/0166423 A1
(43) Pub. Date: Jul. 27, 2006

(54) Removal spacer formation with carbon film

(76) Inventor: Seiji Iseda, Katonah, NY (US)

Correspondence Address: MAYER & WILLIAMS PC, 251 NORTH AVENUE WEST, 2ND FLOOR, WESTFIELD, NJ, 07090, US

(21) Appl. No.: 11/040,782

(22) Filed: Jan. 21, 2005

(51) Int. Cl. H01L 21/8238

(52) U.S. Cl. 438/199

(57) ABSTRACT

A method of making a CMOS device, and a product made by the process. The process includes applying a layer of a carbon film or carbon-containing compound to a substrate. A section of the carbon is etched with a plasma, e.g., an O2, Ar, N2, or He plasma. Ion-implantation, e.g., of As, B, or P, is performed in some of the etched areas, and the carbon is removed with a second plasma.

### FIELD OF THE INVENTION

The invention relates to CMOS device structures, and in particular to high-performance CMOS devices.

### BACKGROUND OF THE INVENTION

The first four figures show a prior art process of making a high-performance CMOS device. Referring to FIG. 1, an initial step is shown of a prior art CMOS device manufacturing process in which a silicon nitride layer 24 has been deposited on a substrate 22. The silicon nitride layer 24 is also referred to here as the first spacer layer, and may have a thickness in the range of about 40-60 nm. Referring next to FIG. 2, a silicon oxide layer 26 and a silicon nitride layer 28 have been deposited on the system of FIG. 1. The silicon nitride layer 28 is also referred to here as the second spacer layer. The silicon oxide layer 26 may have a thickness in the range of about 15-20 nm, and the silicon nitride layer 28 may have a thickness in the range of about 60-100 nm. Each may be deposited in known fashion, e.g., by CVD.

The next step in processing typically involves an etch. FIG. 3 shows the system of FIG. 2 in which an etch gas has been employed in known fashion. The etch gas is typically CxHyFz, although O2, He, Ar, etc. may also be used. The etch gas is used to etch the second spacer layer, i.e., the silicon nitride layer 28. Following use of the etch gas, an ion implantation step is performed over the silicon nitride layer to form regions 23. The etch of the second spacer layer employs an anisotropic condition, as well as detection of the end point to maintain the profile.

However, deleterious consequences result from the use of the etch gas. In particular, the etch gas etches not only the silicon nitride layer 28 but also the silicon oxide layer 26. Furthermore, in the removal process (see FIG. 4) of the second spacer layer, i.e. silicon nitride layer 28, the substrate 22 may undergo deleterious etching, due to the removal of layers that previously protected the same. The removal process etch employs anisotropic condition and typically is etched based on time.

The above prior art process is encumbered with numerous process steps and undesired etching.

### SUMMARY OF THE INVENTION

In one aspect, the invention is directed towards a method of making a CMOS device which includes applying a layer of a carbon film or carbon-containing compound to a substrate. A section of the carbon is etched with a plasma, e.g., an O2, Ar, N2, or He plasma. Ion-implantation, e.g., of As, B, or P, is performed in some of the etched areas, and then the carbon is removed with a second plasma. The carbon-containing compound may include hydrogen or fluorine. In another aspect, the invention is directed to a product made by this process.

Advantages of the invention include the following. An embodiment of the invention provides a more convenient manufacturing process. An embodiment of the invention allows for less undesired etching.

Other advantages will be apparent from the description that follows, including the figures.

### BRIEF DESCRIPTION OF THE DRAWINGS

FIG. 1 shows an initial step of a prior art CMOS device manufacturing process in which a silicon nitride layer has been deposited on a substrate.

FIG. 2 shows the system of FIG. 1 on which has been deposited a silicon oxide layer and a silicon nitride layer.

FIG. 3 shows the system of FIG. 2 in which an etch gas has been employed.

FIG. 4 shows the system of FIG. 3 in which the second silicon nitride layer has been removed.

FIG. 5 shows a first embodiment of a CMOS device manufacturing process according to the invention in which a silicon nitride layer has been deposited on a substrate.

FIG. 6 shows the results of a oxygen plasma etch of the device of FIG. 5.

FIG. 7 shows results of an ion-implantation step of the device of FIG. 6. a silicon oxide etch back according to an embodiment of the invention.

FIG. 8 shows the results of a oxygen plasma etch of the device of FIG. 7 to remove a spacer film.

FIG. 9 shows a second embodiment of a CMOS device manufacturing process according to the invention

FIG. 10 shows the results of a carbon film deposition over the device of FIG. 9.

FIG. 11 shows results of an oxygen plasma etch and ion-implantation step of the device of FIG. 10.

FIG. 12 shows the results of an oxygen plasma etch of the device of FIG. 11 to remove a spacer film.

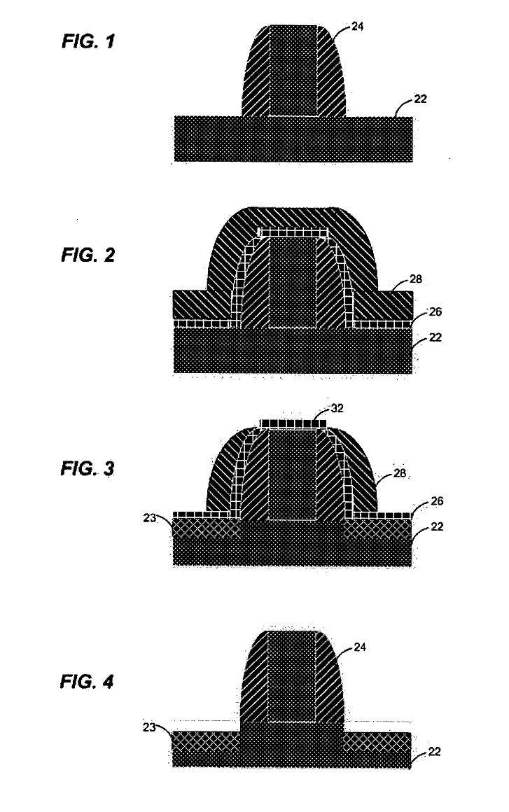

Note that in all figures, like shading may generally represent like elemental composition or like compounds. Not all elements have reference numerals, for clarity.

### DETAILED DESCRIPTION

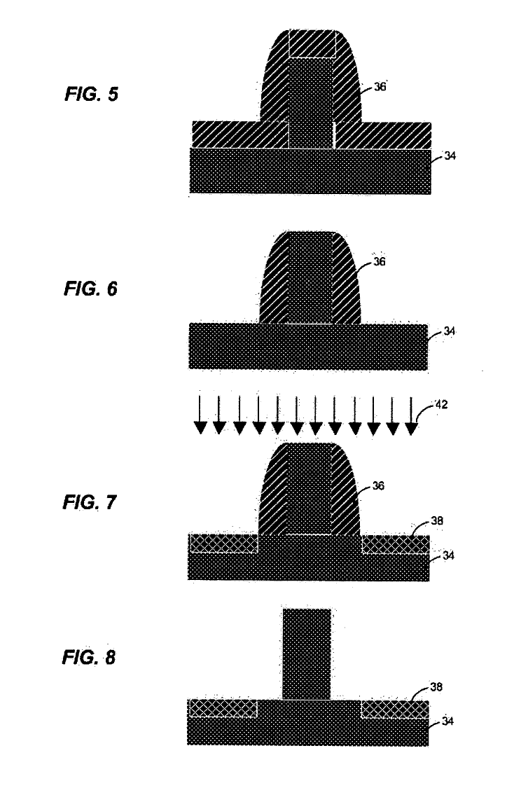

Referring to FIG. 5, a first embodiment is shown of a CMOS device manufacturing process according to the invention in which a carbon mask spacer layer 36 has been deposited on a substrate 34. The carbon mask layer 36 may be deposited in a number of ways, including via depositing a carbon compound comprising hydrogen or fluorine. In such cases, the hydrogen or fluorine constituent may be removed with an oxygen plasma.

Referring to FIG. 6, results are shown of an RIE process such as an oxygen plasma etch of the device of FIG. 5. In particular, an oxygen plasma etch is employed to remove a portion of the carbon mask layer 36 as shown. Other types of gases may also be used, with associated operating regimes. These other gases may include, e.g., argon, nitrogen, and helium. Relevant parameters for such an etch include pressure, power, gas species, gas ratio, temperature, time and end point detection. Following the oxygen plasma etch, an ion-implantation step may be performed (see element 42 of FIG. 7). Typical types of ions that would be implanted may be, e.g., P, As, or B. The results of the ion-implantation step are implantation areas 38, which may be about 50 nm deep.

Following such implantation, and referring to FIG. 8, an oxygen plasma etch of the device of FIG. 7 may be performed to remove the carbon spacer film. A wet etch may also be employed. Besides oxygen, C12 and O2 may also be employed to etch carbon, although the selectivity would be required to be high. The result of the steps of FIGS. 5-8 are a more conveniently-manufactured device having less deleterious etching. Other advantages inure as well, including that an etch stop film is no longer necessary in the spacer etch, particularly as the oxygen plasma cannot etch the substrate. Further, a process step can be removed because the carbon spacer film and the photoresist can be removed by the same oxygen plasma in the same step.

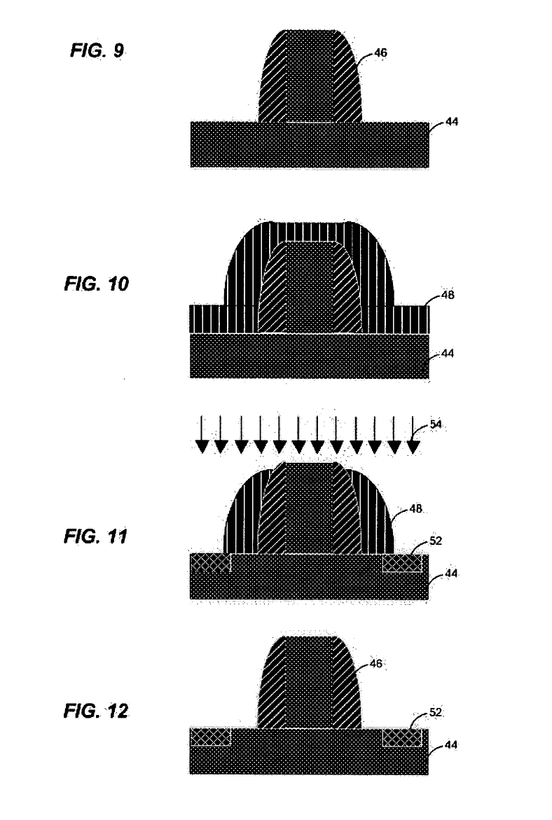

Referring to FIG. 9, a second embodiment is shown of a CMOS device manufacturing process according to the invention in which an underlayer layer 46, i.e., a first spacer layer, has been deposited on a substrate 44. Underlayer 46 may be made of silicon oxide or silicon nitride, and may be deposited with a CVD process. Referring to FIG. 10, results are shown of a carbon film spacer layer 48 deposition over the device of FIG. 9. Carbon film spacer layer 48 may also be deposited with CVD.

FIG. 11 shows results of an oxygen plasma etch and ion-implantation step of the device of FIG. 10. In particular, the oxygen plasma etch is used to remove certain portions of the carbon film spacer layer 48. The ion-implantation step is indicated by element 54, and the result is implantation areas 52.

Finally, and referring to FIG. 12, the results are shown of an oxygen plasma etch of the device of FIG. 11 to remove the carbon film spacer layer 48. It is noted that the underlayer 46 is used because there are PFETs and NFETs present on the same chip. Sometimes one of the varieties of FETs requires the carbon spacer, while the other variety does not. In this case, the underlayer 46 is used so that at least one such layer is present between the device and the substrate.

The result of the steps of FIGS. 9-12 are a more conveniently-manufactured device having less deleterious etching. Other advantages inure as well, including that an etch stop film is no longer necessary in the spacer etch, particularly as the oxygen plasma cannot etch the substrate.

The invention has been described with respect to certain embodiments. However, the invention is not to be limited to those embodiments described; rather, the invention is limited solely by the claims appended hereto, and equivalents thereof.

1. A method of making a CMOS device, comprising:
applying a first layer of carbon film or carbon-containing compound to a substrate;
etching a predetermined section of the first layer wit a first plasma;
performing an ion-implantation step to implant ions in at least a portion of the etched areas; and
removing the first layer with a second plasma.

2. The method of claim 1, wherein the first plasma is an oxygen plasma.

3. The method of claim 1, wherein the second plasma is an oxygen plasma.

4. The method of claim 1, wherein the ions are chosen from the group consisting of: As, B, and P.

5. A product produced by the process of claim 1.

6. The method of claim 1, wherein the carbon-containing compound includes hydrogen or fluorine.

7. The method of claim 1, wherein the first or second plasmas are chosen from the group consisting of: Ar, nitrogen, and He.

8. A method of making a CMOS device, comprising:
depositing an underlayer on a substrate;
applying a first layer of carbon film or carbon-containing compound to the underlayer,
etching a predetermined section of the first layer with a first plasma;
performing an ion-implantation step to implant ions in at least a portion of the etched areas; and
removing the first layer with a second plasma.

9. The method of claim 8, wherein the first plasma is an oxygen plasma.

10. The method of claim 8, wherein the second plasma is an oxygen plasma.

11. The method of claim 8, wherein the ions are chosen from the group consisting of: As, B, and P.

12. A product produced by the process of claim 8.

13. The method of claim 8, wherein the carbon-containing compound includes hydrogen or fluorine.

14. The method of claim 8, wherein the first or second plasmas are chosen from the group consisting of: Ar, nitrogen, and He.
